(19) United States
(12) Patent Application Publication
(10) Pub. No.: US 2026/0182277 A1
(43) Pub. Date: Jun. 25, 2026

(54) SEMICONDUCTOR DEVICE INCLUDING AN ULTRATHIN CONTROLLER DIE

(71) Applicant: Sandisk Technologies, Inc., Milpitas, CA (US)

(72) Inventors: Xu Chen, Shanghai (CN); Rui Guo, Shanghai (CN); Zengyu Zhou, Shanghai (CN); Rui Yuan, Shanghai (CN); Yihao Chen, Shanghai (CN); Xiaoting Guo, Shanghai (CN); Cong Zhang, Shanghai (CN); Jihao Tang, Shanghai (CN); Wenbin Qu, Shanghai (CN); Weng Khoon Mong, Shanghai (CN)

(73) Assignee: Sandisk Technologies, Inc., Milpitas, CA (US)

(21) Appl. No.: 18/988,097

(22) Filed: Dec. 19, 2024

(51) Int. Cl. H01L 21/3065; H01L 23/00

(52) U.S. Cl. CPC H10P 50/242; H10W 74/15; H10W 90/724; H10W 90/734

(57) ABSTRACT

A semiconductor device includes an ultrathin controller die. In embodiments, a semiconductor die is be mounted on a substrate. The die may be thinned by backgrinding before being mounted on the substrate. Thereafter, a protective coating is applied to the die and substrate, and the protective coating is processed to expose an upper, inactive surface of the die. The die is then thinned by a plasma etching process to partially or completely remove the inactive silicon layer of the die. Thereafter, the protective coating may be removed leaving only the ultrathin die on the substrate. In some embodiments, the die is a memory controller die.

### BACKGROUND

The strong growth in demand for portable consumer electronics is driving the need for high-capacity storage devices. Non-volatile semiconductor memory devices are widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, computers, cellular telephones and SSD (solid state drives).

While many varied packaging configurations are known, flash memory semiconductor packages may in general be assembled as system-in-a-package (SIP), where a controller die, such as an ASIC, and a number of memory dies are mounted and interconnected to an upper surface of substrate such as a printed circuit board. The package may then be encased in a mold compound.

There is an ongoing need to decrease the thickness of semiconductor packages while maintaining or improving storage capacity. One limiting feature in this endeavor is the thickness of the controller die. Conventional controller dies have a device layer including logic circuitry of about 10 to 20 μm built over an inactive silicon layer which is typically about 30 to 50 μm. It is difficult to further reduce the thickness of the device layer, but of late there has been an interest in attempting to reduce the thickness of the silicon layer. However this has proved challenging.

One reason is that a controller die thinned below about 60 μm often fails due to problems such as bump crack and wafer burnout. Bump crack refers to the metal bumps or contacts which are used to connect the controller die to a substrate. Where wafers are ground too thin, the bumps are subjected to high mechanical stresses causing micro-cracks or fractures in the bumps which often compromises their structural integrity. Wafer burnout refers to damage to the controller die during the thinning backgrinding process. When the controller die and wafer is ground too thin, heat buildup from friction during the grinding becomes more significant. This heat can damage or burnout the device layer of the controller die.

Another difficulty in thinning controller dies is that when a wafer of controller dies is thinned beyond some threshold, such as 60 μm, the wafer becomes very fragile and is difficult to handle or process further without cracking.

### DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is a flowchart of the overall fabrication process of a semiconductor device and controller according to embodiments of the present invention.

FIG. 2 is a top view of a substrate for use in a semiconductor device according to an embodiment of the present technology.

FIG. 3 is a cross-sectional edge view of the controller die during fabrication of a semiconductor device according to embodiments of the present technology.

FIG. 4 is a top view of a controller die mounted on a substrate according to an embodiment of the present technology.

FIG. 5 is a partial cross-sectional view of the controller die mounted on a substrate during an initial stage of assembly according to embodiments of the present technology.

FIG. 6 is a partial cross-sectional view of the controller die mounted on a substrate during a second stage of assembly according to embodiments of the present technology.

FIG. 7 is a partial cross-sectional view of the controller die mounted on a substrate during a third stage of assembly according to embodiments of the present technology.

FIG. 8 is a partial cross-sectional view of the controller die mounted on a substrate during a fourth stage of assembly according to embodiments of the present technology.

FIG. 9 is a partial cross-sectional view of the controller die mounted on a substrate during a fifth stage of assembly according to embodiments of the present technology.

FIG. 10 is a partial cross-sectional view of the controller die mounted on a substrate during a fifth stage of assembly according to alternative embodiments of the present technology.

FIG. 11 is a partial cross-sectional view of the controller die mounted on a substrate during a sixth stage of assembly according to embodiments of the present technology.

FIG. 12 is a top view of a controller die and flash memory dies mounted on a substrate according to an embodiment of the present technology.

FIG. 13 is a cross-sectional view of a semiconductor device at a final stage of assembly according to embodiments of the present technology.

### DETAILED DESCRIPTION

The present technology will now be described with reference to the drawings, which in embodiments, relate to a semiconductor device including an ultrathin controller die formed in a safe and efficient process. In embodiments, a controller die may be mounted on a substrate. Thereafter, a protective coating may be applied to the controller die and substrate, and the protective coating is then processed to expose an upper, inactive surface of the full-thickness controller. The controller may then be thinned by a process such as plasma etching to partially or completely remove the inactive silicon layer of the controller die. Thereafter, the protective coating may be removed leaving only the ultrathin controller die on the substrate.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details. For example, although the invention is described as a controller die, other semiconductor dies could also benefit from the invention, such memory dies, System on a Chip dies, microprocessor dies, etc.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

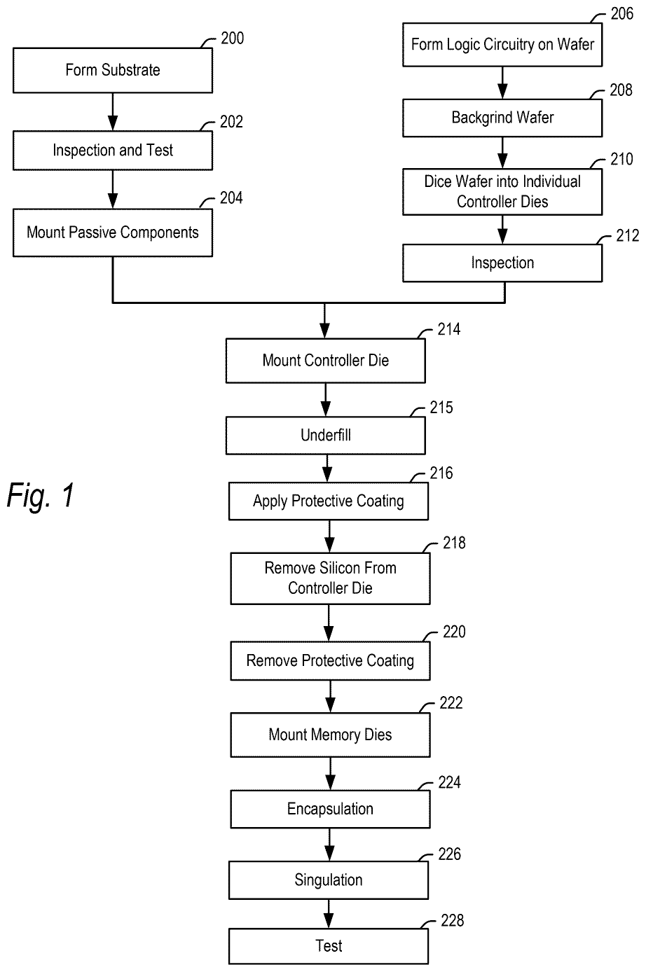

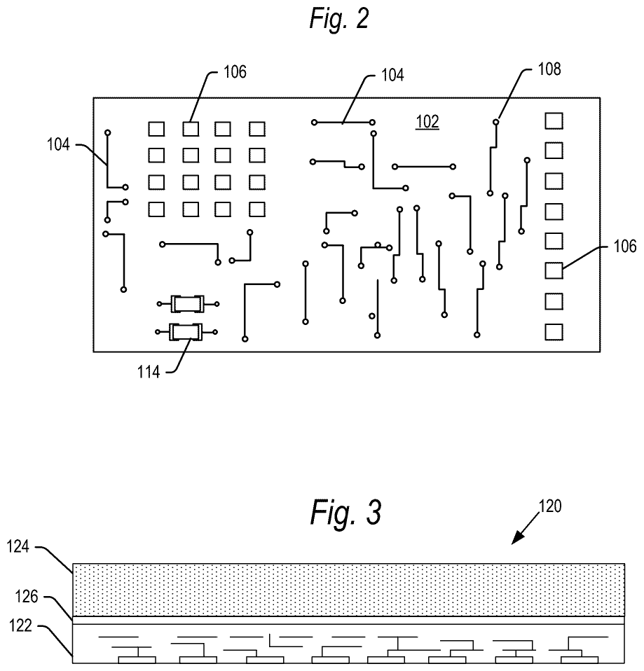

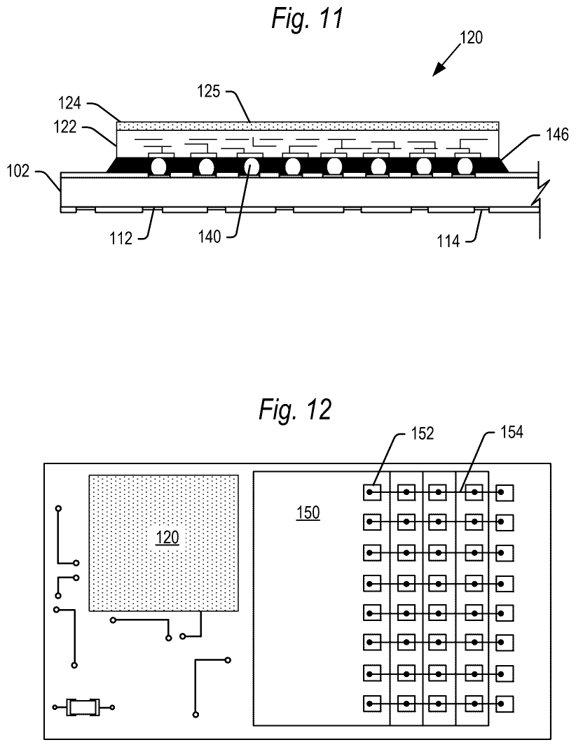

An embodiment of the present invention will now be explained with reference to the flowchart of FIG. 1 and the top and edge views of FIGS. 2 through 13. A substrate 102 for supporting a controller die of the present technology may be formed in step 200 as shown in the top view of FIG. 2. The substrate 102 may be formed on a panel including a plurality of such substrates to achieve economies of scale. The substrate 102 may be a variety of different chip carrier mediums for transmitting signals between semiconductor dies on the substrate and a host device. Such chip carrier mediums may include a printed circuit board (PCB), a leadframe or a tape automated bonded (TAB) tape. Where substrate 102 is a PCB, the substrate may be formed of top and bottom conductive layers, and possibly one or more intermediate conductive layers, each separated by a dielectric layer. The core may be formed of various dielectric materials such as for example, polyimide laminates, epoxy resins including FR4 and FR5, bismaleimide triazine (BT), and the like. The conductive layers may be formed of copper or copper alloys, plated copper or plated copper alloys, Alloy 42 (42Fe/58Ni), copper plated steel, or other metals and materials known for use on substrate panels.

Conductance patterns are formed in one or more of the top, bottom and intermediate conductive layers. The conductance pattern(s) may include electrical traces 104 and contact pads 106 as shown for example in FIG. 2. The traces 104 and contact pads 106 (only some of which are numbered in the figures) are by way of example, and the substrate 102 may include more traces and/or contact pads than are shown in the figures. Electrically conductive vias 108 may be formed through a thickness of the substrate 102, electrically coupling two or more conductive layers of the substrate. The vias 108 (only some of which are numbered in the figures) are by way of example, and the substrate 102 may include more vias 108 than are shown in the figures, and they may be in different locations than are shown in the figures.

The upper conductance pattern of the substrate 102 may be etched to include contact pads 106 for receiving solder balls and/or electrical traces as explained below. The lower conductance pattern of the substrate 102 may also be etched to include contact pads 112 (FIG. 5) for receiving solder balls as explained below. The conductance patterns on the top and/or bottom surfaces of the substrate 102 may be formed by a variety of known processes, including for example various photolithographic processes. A solder mask may be applied over the conductance patterns in the top and bottom surfaces, leaving the various contact pads 106, 112 exposed.

The substrate 102 may next be inspected and tested in step 202 to check electrical operation, and for contamination, scratches and discoloration. Assuming the substrate 102 passes inspection, passive components 114 (FIG. 2) may be affixed to the substrate in a step 204. The one or more passive components may include for example one or more capacitors, resistors and/or inductors, though other components are contemplated. The passive components 114 shown are by way of example only, and the number, type and position may vary in further embodiments.

Before, after or in parallel with the formation of substrate 102, a controller die 120 as shown in the cross-sectional side view of FIG. 3 may be formed on a wafer in steps 206-210, as is known by those of skill in the art and explained below. The controller die 120 may for example be an application-specific integrated circuit (ASIC) semiconductor controller for controlling the operation of other semiconductor dies, such as for example semiconductor memory dies shown in FIG. 12 and described below. In further embodiments, the controller die 120 may be a specialized controller or microcontroller, including for example a graphics processing unit or an artificial intelligence (AI) processing unit. The controller die 120 may be other types of controllers in further embodiments.

The controller die 120 may be fabricated on a wafer including a plurality of such controller dies to achieve economies of scale. In step 206, logic circuitry may be formed to define the individual controller dies of the wafer. As shown in the cross-sectional edge view of FIG. 3, the controller die 120 may include a device layer 122 of logic circuits formed over an inactive silicon layer 124. An oxide layer 126 may be formed between the device layer 122 and silicon layer 124 to isolate the device layer and reducing electrical interference and parasitic capacitance. The device layer 122 may be formed through photolithography to define patterns, etching to shape components, and doping to form transistor regions. Metal layers are then deposited to create connections between transistors, forming the logic circuits. Once the circuits are completed, typically by a semiconductor fabrication facility or semiconductor fab, the wafer is shipped to a backend or assembly facility. At the assembly facility, the wafer may be thinned by backgrinding in step 208 as is known in the art, and then a dicing process may be performed in step 210 to form individual controller dies 120. Each controller die 120 may undergo inspection and functional testing in step 212.

After the fabrication of the device layer 122, the opposed surface of silicon, referred to herein as the inactive surface 125, may be thinned in a backgrind process, as discussed above. In embodiments, after backgrinding, the device layer 122 may be 10 to 20 μm thick, and the silicon layer 124 may be 30 of 50 μm thick. The oxide layer 126 may be 50 to 200 nm thick. It is understood that each of these dimensions may vary, proportionately and disproportionately to each other, in further embodiments.

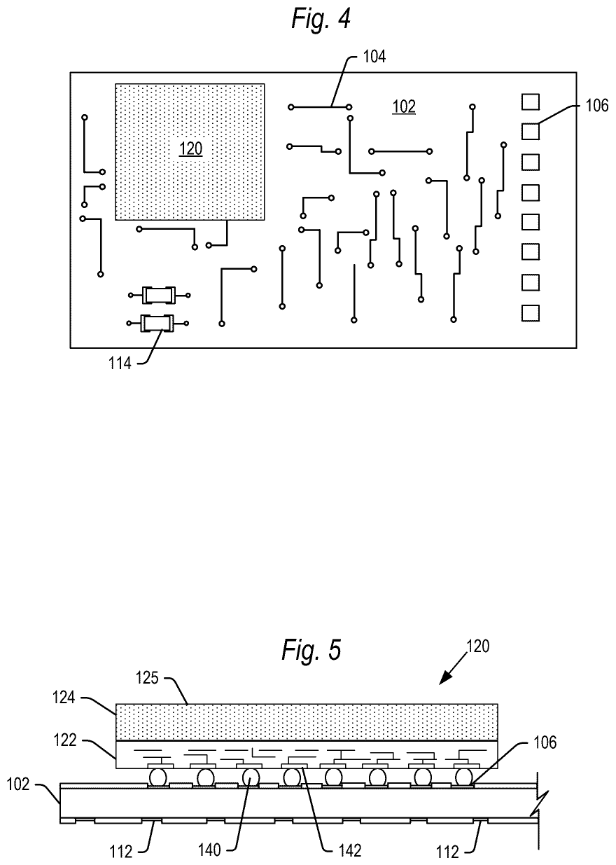

In step 214, the controller die 120 may be mounted to the substrate 102 in a flip-chip configuration as shown in FIG. 4 and the view of FIG. 5. FIG. 5 is a cross-sectional edge view of a portion of the substrate 102 including the controller die 120. The controller die 120 may be mounted to the substrate using solder balls 140. The solder balls 140 may be affixed to contact pads 106 on the substrate 102, and to bond pads 142 formed on the active surface of the controller die 120 (i.e., the surface of the controller die 120 including the device layer 122). Once connected, the solder balls 140 may be reflowed to physically couple the controller die 120 to the substrate 102. The solder balls 140 further electrically couple the bond pads 142 of the controller die 120 to the contact pads 106 of the substrate.

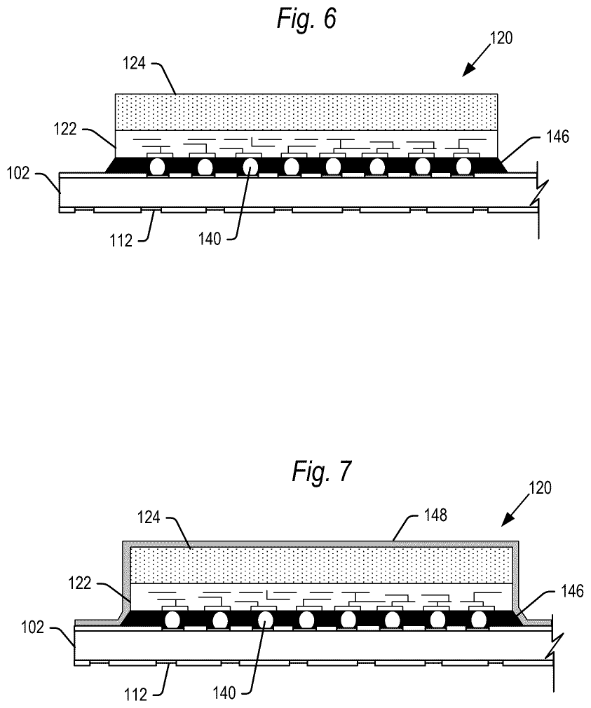

Following mounting of the controller die 120, an underfill material 146 may be injected into the space between the controller die 120 and substrate in step 215 and as shown in FIG. 6. In addition to relieving stress on the solder balls 140, the underfill material 146 may be an epoxy resin, possibly loaded with silica or other fillers to improve its thermal and mechanical properties. The underfill material 146 may be dispensed as a liquid and then cured by heating to form a solid layer that reinforces the connection between the controller die 120 and substrate 102.

In accordance with aspects of the present technology, the controller die 120 is further thinned after being mounted to the substrate 102 in a way that has none of the negative aspects discussed in the Background section. This process will now be described with reference to steps 216-220 and FIGS. 7-11.

In step 216, a thin protective mask layer 148 is applied over the horizontal and vertical surfaces of the controller die 120 and onto at least portions of the upper surface of the substrate 102. The protective mask layer 148 may consist of a polymer-based photoresist, a silicon dioxide layer, a silicon nitride layer or some other durable, chemically resistant material. As explained below, the controller die 120 may be thinned by plasma ion etching so the protective mask layer 148 is chosen for its resistance to the reactive ions in the plasma. In embodiments, the protective mask layer 148 may be 1 to 10 μm thick, though it may be thicker or thinner than that in further embodiments.

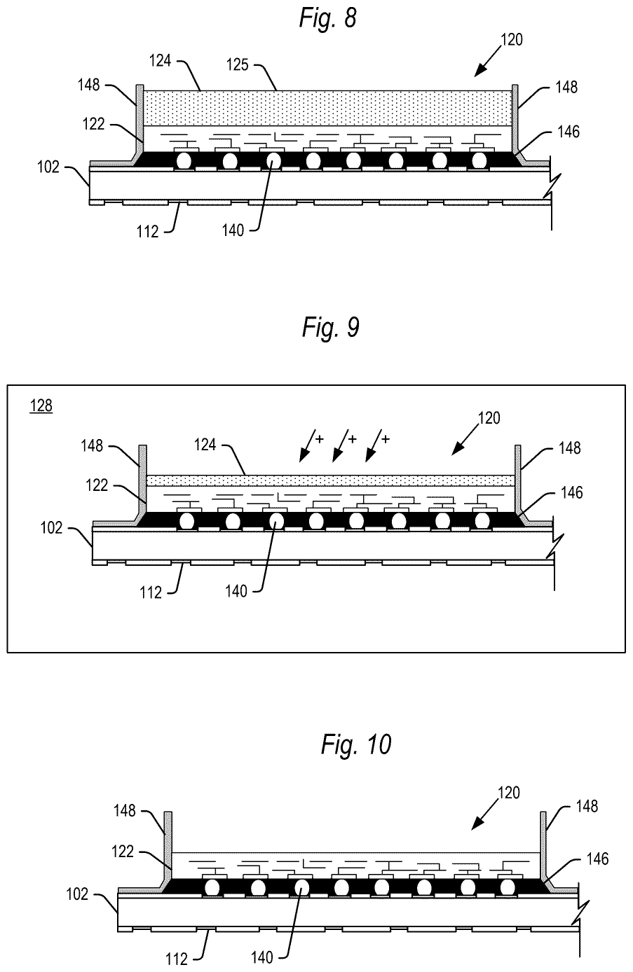

The protective mask layer 148 may be processed to remove that portion of the protective mask layer covering the inactive surface 125 of the controller die 120, facing up away from the substrate, as shown in FIG. 8. The protective mask layer 148 may be removed from the inactive surface of the controller die 120 by a variety of methods, including wet chemical etching. For example, where the mask layer 148 is a photoresist mask, a solvent-based chemical, such as acetone may be used to remove the mask. Where the mask layer 148 is a silicon mask, an etchant such as hydrofluoric or phosphoric acid may be used to remove the mask. In further embodiments, the upper inactive surface of the controller die 120 may be covered when the protective mask layer 148 is applied so that the inactive surface remains uncovered when the mask 148 is applied, as shown in FIG. 8.

In step 218, the controller die 120 is thinned by removing some or all of the inactive silicon layer 124 through the exposed inactive surface 125. In embodiments, this may be done by plasma etching the silicon layer 124. In such embodiments, the substrate 102 with controller die 120 may be placed in a plasma etching chamber 128, shown schematically in FIG. 9. In the chamber 128, plasma is created by applying a strong electric field to a gas in the presence of a partial or full vacuum. Any of various reactive gasses may be used, such as argon, oxygen, or a mixture of reactive gases, such as sulfur hexafluoride or other fluorine-based gases. When energized, these gas molecules dissociate into reactive ions (+) in the plasma, which then collide with the surface 125 of the controller die 102 as shown to chemically and/or physically react with the silicon layer 124. This chemical and/or physical reaction gradually removes the silicon layer 124 at the inactive surface 125 in a highly controlled process to thin the controller die 120 to a desired thickness. The plasma etch process may use radicals or neutral species in further embodiments.

The plasma etching process may be made isotropic or anisotropic by manipulating the electric field and pressure in the chamber 128. To further control the etching rate and achieve uniform thinning, parameters such as gas flow rate, chamber pressure, RF power, temperature and processing time may all be monitored and adjusted. Control of these parameters allows for highly controlled thinning of the silicon layer 124 without compromising the integrity of the device layer 122. The surfaces of the controller die 120 and substrate 102 covered by the protective mask 148 remain unaffected by the plasma.

In one embodiment shown in FIG. 9, the silicon layer 124 may be thinned to between 1 and 10 μm, though it may be thinner or thicker than that in further embodiments. In a still further embodiment shown in FIG. 10, the silicon layer 122 may be completely removed. In this embodiment, the oxide layer 126 may be left intact, or the oxide layer 126 may be removed as well, leaving only the device layer 122.

In the embodiments described above, the controller die 120 is thinned by plasma etching, which may be a preferred method given its ability to precisely control die thicknesses without damage to the device layer 122. However, it is understood that other techniques may be used to controllably thin the controller die 120 in further embodiments. Such further techniques include chemical-mechanical polishing (CMP), which is a process that smooths and planarizes surfaces by combining chemical and mechanical forces. In CMP, the substrate 102 may be supported on a chuck, and the inactive surface 125 of the controller die 120 may be pressed against a rotating polishing pad that is saturated with a slurry containing abrasive particles and/or chemical agents. The abrasive particles physically remove material from the surface, while the chemicals in the slurry react with the surface material to soften it and enhance the removal rate. By controlling and adjusting parameters such as pad pressure, particle size, slurry composition, and rotational speed, CMP can thin or remove the silicon layer 124 without damaging the device layer 122.

In another embodiment, the inactive surface 125 may be thinned by wet chemical etching. In one example of wet chemical etching, solutions containing for example potassium hydroxide (KOH) or tetramethylammonium hydroxide (TMAH) may be used for thinning the silicon-based layer(s) of the controller die. The controller die 102 may be submerged in the etchant solution, which gradually removes material in a controlled manner. The protective mask 148 may be used to protect surfaces other than the inactive surface 125.

In a still further embodiment, the inactive surface 125 of the controller die 120 may be controllably thinned by laser ablation. Laser ablation uses focused laser energy to vaporize the inactive surface 125 in a highly controlled thinning process. The laser can be precisely adjusted to remove specific amounts of the silicon layer 124 without damage to the device layer 122.

The above methods of thinning result in an ultrathin controller die 120 while avoiding the problems of the prior art, such as wafer cracking, bump cracking and die burnout. Moreover, the underfill layer 146 provides additional structural rigidity to further reduce stress forces on the solder balls 140 during the above-described thinning processes and further assembly of the semiconductor device including the controller die 102.

After this further thinning of the controller die 120, the protective mask layer 148 may be removed from the vertical edges of the controller die 120 and on the substrate 102 in step 220. Any of the above-described techniques may be used to remove the protective mask layer 148.

In step 222, one or more semiconductor memory dies 150 may be mounted on the substrate 102 as shown in the top view of FIG. 12 and the completed cross-sectional view of FIG. 12. In embodiments, the memory dies 150 may be mounted next to the controller die 120 on the substrate 102. The semiconductor memory dies 150 may be conventional flash memory semiconductor dies such as Bit Cost Scalable (BiCS) dies or other NAND dies, diced from a wafer and positioned on substrate 102 with a pick and place robot. In further embodiments, the memory dies 150 may be volatile memory dies such as RAM or DRAM.

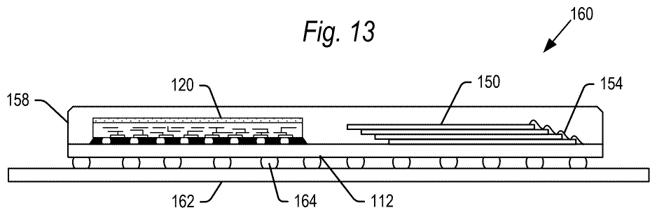

FIGS. 12 and 13 show 4 memory dies 150 mounted on substrate 102. However, there may be more or less semiconductor memory dies 150 in further embodiments including for example 1, 2, 8, 16, 32, 64 or other numbers of dies. The memory dies 150 are shown in a stepped, offset configuration with the bond pads 152 of each semiconductor die left exposed. This allows the memory dies 150 to be electrically connected to each other and the substrate 102 by bond wires 154 in a known wire bonding process. It is understood that semiconductor memory dies 150 may be electrically coupled to each other and the substrate 102 by other methods in further embodiments, including by through silicon vias or flip-chip coupling technologies.

After mounting of the memory dies 150 on the substrate 102, the controller die 120 and memory dies 150 may be encapsulated in an encapsulant such as mold compound 158 in step 224 and as shown in FIG. 13. The encapsulation step 224 may be performed by positioning the panel of substrates 102 within a mold chase and injecting liquid mold compound over the controller die 120 and memory dies 150. Other encapsulation processes may be used, including for example FFT (Flow Free Thin) compression molding, in further embodiments. The underfill material 146 reduces or prevents stress on the ultrathin controller die 120 and solder balls 140. Mold compound 158 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other encapsulants from other manufacturers are contemplated.

The respective substrates 102 may be singulated from the panel of substrates in step 226 to form a finished semiconductor device 160 as shown in FIG. 13. Each semiconductor device 160 may be singulated by any of a variety of cutting methods including sawing, water jet cutting, laser cutting, water guided laser cutting, dry media cutting, and diamond coating wire cutting. While straight line cuts will define generally rectangular or square shaped semiconductor devices 160, it is understood that devices 160 may have shapes other than rectangular and square in further embodiments of the present technology. Once cut into individual devices 160, the devices may be tested in a step 228 to ensure the devices are functioning properly.

As shown in FIG. 13, the finished semiconductor device 160 may be mounted on a host device 162 such as a printed circuit board. The device 160 may be physically and electrically coupled to the host device 162 by solder balls 164 affixed to contact pads 112 on the bottom surface of the substrate 102.

In summary, in one example, the present technology relates to a semiconductor device, comprising: a substrate; a semiconductor controller die physically and electrically mounted to the substrate, wherein the semiconductor controller die comprises a device layer, and wherein the semiconductor die is devoid of an inactive silicon layer or wherein the inactive silicon layer is thinner than the device layer; and an underfill layer for filling a space between the semiconductor controller die and the substrate.

In another example, the present technology relates to a method of assembling a semiconductor device, comprising the steps of: (a) mounting a semiconductor controller die onto a substrate with an active layer of the semiconductor controller die facing the substrate and an inactive layer of the semiconductor controller die facing away from the substrate; and (b) thinning the inactive layer of the semiconductor controller die after the semiconductor controller die is mounted on the substrate.

In a further example, the present technology relates to a method of assembling a semiconductor device, comprising the steps of: (a) mounting a semiconductor controller die onto a substrate with an active layer of the semiconductor controller die facing the substrate and an inactive layer of the semiconductor controller die facing away from the substrate, said step (a) comprising the step of mounting the semiconductor controller die onto the substrate using solder balls; (b) underfilling a space between the semiconductor controller die and the substrate with an underfill material; (c) thinning the inactive layer of the semiconductor controller die after the semiconductor controller die is mounted on the substrate by plasma etching; and (d) mounting one or more semiconductor memory dies on the substrate.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a substrate;
a semiconductor die physically and electrically mounted to the substrate, wherein the semiconductor die comprises a device layer, and wherein the semiconductor die is devoid of an inactive silicon layer or wherein the inactive silicon layer is thinner than the device layer; and
an underfill layer for filling a space between the semiconductor die and the substrate.

2. The semiconductor device of claim 1, wherein the semiconductor die is flip-chip mounted to the substrate by a plurality of solder balls.

3. The semiconductor device of claim 1, wherein the semiconductor die is thinned after being mounted onto the substrate.

4. The semiconductor device of claim 1, wherein the semiconductor die is devoid of an inactive silicon layer.

5. The semiconductor device of claim 1, wherein the semiconductor die comprises the device layer and an inactive silicon layer.

6. The semiconductor device of claim 5, wherein the inactive silicon layer is thinned after the semiconductor die is mounted on the substrate.

7. The semiconductor device of claim 1, wherein the semiconductor die further comprises an oxide layer adjacent the device layer.

8. The semiconductor device of claim 1, wherein the semiconductor die is one of an ASIC, a memory controller, a graphics processing unit and an artificial intelligence processor.

9. The semiconductor device of claim 1, further comprising one or more semiconductor memory dies mounted on the substrate and controlled by the semiconductor die.

10. The semiconductor device of claim 9, further comprising mold compound for encapsulating the semiconductor die and the one or more semiconductor memory dies.

11. A method of assembling a semiconductor device, comprising the steps of:
(a) mounting a semiconductor die onto a substrate with an active layer of the semiconductor die facing the substrate and an inactive layer of the semiconductor die facing away from the substrate; and
(b) thinning the inactive layer of the semiconductor die after the semiconductor die is mounted on the substrate.

12. The method of claim 11, wherein said step (a) of mounting the semiconductor die onto the substrate comprises the step of mounting the semiconductor die onto the substrate using solder balls.

13. The method of claim 12, further comprising the step (c) of filling a space around the solder balls and between the semiconductor die and substrate with an underfill material.

14. The method of claim 11, further comprising the step (d) of mounting one or more semiconductor memory dies on the substrate.

15. The method of claim 11, wherein said step (b) of thinning the inactive layer of the semiconductor die comprises the step of thinning the inactive layer of the semiconductor controller die by plasma etching.

16. The method of claim 15, further comprising the step of applying a protective mask over the semiconductor die and at least portions of the substrate, and removing the protective mask over an inactive surface of the semiconductor die.

17. The method of claim 15, further comprising the step of applying a protective mask over portions of the semiconductor die except an inactive surface of the semiconductor die, and applying the protective mask over at least portions of the substrate.

18. The method of claim 11, wherein said step (b) of thinning the inactive layer of the semiconductor die comprises the step of thinning the inactive layer of the semiconductor die by one of chemical-mechanical polishing, wet chemical etching and laser ablation.

19. The method of claim 11, wherein said step (b) of thinning the inactive layer of the semiconductor die comprises the step of entirely removing the inactive layer of the semiconductor die.

20. A method of assembling a semiconductor device, comprising the steps of:
(a) mounting a semiconductor die onto a substrate with an active layer of the semiconductor die facing the substrate and an inactive layer of the semiconductor die facing away from the substrate, said step (a) comprising the step of mounting the semiconductor die onto the substrate using solder balls;
(b) underfilling a space between the semiconductor die and the substrate with an underfill material; and
(c) thinning the inactive layer of the semiconductor die after the semiconductor controller die is mounted on the substrate by plasma etching.
